(19) United States
(12) Patent Application Publication
(10) Pub. No.: US 2005/0003194 A1
(43) Pub. Date: Jan. 6, 2005

(54) Method for making diamond-coated composite materials

(76) Inventors: Dominique Michau, Bordeaux (FR); Gerard Demazeau, Gradignan (FR); Alain Largeteau, Cestas (FR); Jean-Pierre Manaud, Saint Loubes (FR)

Correspondence Address: Blakely Sokoloff;Taylor & Zafman, 7th Floor, 12400 Wilshire Boulevard, Los Angeles, CA, 90025, US

(21) Appl. No.: 10/483,844

(22) PCT Filed: Jul. 12, 2002
(86) PCT No.: PCT/FR02/02476

(30) Foreign Application Priority Data
Jul. 13, 2001 (FR) 01/09357

(51) Int. Cl. C23C 16/00; B32B 9/00

(52) U.S. Cl. 428/408; 427/249.7

(57) ABSTRACT

The invention concerns a method for making a diamond-coated composite material comprising deposition on a substrate of an intermediate layer and deposition on the intermediate layer of a diamond coating. The invention is characterised in that the intermediate layer is an expansible layer capable of producing chemical bonds with the substrate while chemically developing during deposition of the diamond coating. The invention is applicable to a large number of articles and components made of diamond composite.

The present invention relates to diamond-coated composites.

Diamond-coated composites comprising a substrate to which a layer of diamond or of diamond-like carbon is applied have been known for a long time.

Such coatings are usually deposited on the substrate using the CVD (chemical vapor deposition) technique for obtaining coatings having a thickness of several microns.

The two basic publications with regard to the CVD technique are:
(a) “Vapour Growth of Diamond on Diamond and Other Surfaces” by B. V. Spitsyn et al., J of Crystal Growth 52 (1981), 219-26;
(b) “Growth of Diamond Particles from Methane-Hydrogen Gas” by S. Matsumoto et al., J. of Materials Science 17 (1982), 3106-12.

However, it has been found that the use of such materials coated in this way are brittle, the brittleness arising essentially from the internal tensile stresses in the coating, from its poor adhesion to the substrate and from the difference in thermal conductivity between the coating (having a high conductivity) and the substrate (having a lower conductivity).

In certain cases, the chemical composition of the substrate promotes the formation of graphite to the detriment of that of diamond.

To solve these problems, it has been proposed to interpose an interlayer between the substrate and the diamond coating. For example, in the case of a substrate chosen from the group comprising a hard metal compound linked via a metal, patent EP 0 166 708 provides an interlayer consisting of titanium.

U.S. Pat. No. 6,165,616 also proposes the use of an interlayer, but by predetermining and controlling the thickness and the properties of this interlayer as it is being deposited in order to reduce the tensile stress in the coating.

The information contained in the aforementioned prior art documents, in particular with regard to the various forms of the CVD technique, are incorporated into the present description by way of reference.

The present invention relates to the aforementioned field of diamond-coated composites comprising an interlayer applied to the substrate and an external diamond coating applied to the interlayer.

According to the essential feature of the invention, the interlayer is chosen in such a way that it can form chemical bonds with the substrate, while being chemically developable during diamond deposition so as to increase the substrate/interlayer and interlayer/diamond layer adhesion.

According to another feature of the invention, the interlayer is subjected to a surface treatment and the substrate/interlayer assembly undergoes an annealing heat treatment, all this before diamond deposition.

The invention therefore proposes a process for producing a diamond-coated composite comprising, in succession, the deposition on the substrate of a developable interlayer, the surface treatment of the interlayer and the annealing of the substrate/interlayer assembly and the deposition of a polycrystalline diamond coating by CVD techniques.

The present invention thus relates both to a diamond-coated composite and to its manufacturing process.

It also relates to the articles or parts comprising a substrate thus coated. The fields of application vary widely, including in tribology, (see for example antifriction coatings), in the mechanical field (machine tools and/or grinding tools), in optics (reflective surface used in optical transfers), in electronics (heat sinks, semiconductors, etc.).

The invention applies to the most diverse of substrates insofar as the developable interlayer is chosen according to the composition and the structure of the substrate in order to favor the creation of chemical bonds, both to the substrate and to the diamond coating, during the diamond deposition step.

The description that follows, especially with reference to the appended drawings, will make it more clearly understood how the invention can be realized in one particular substrate example, revealing other features and advantages of the invention.

The substrate used in this example consists of a cobalt-alloyed tungsten carbide WC, the proportion of cobalt by weight ranging from 3 to 20%.

It is known that cobalt, even in small quantities, can direct the formation of sp²-type carbon, which results in diamond layers of poor quality owing to the incorporation of graphitic carbon.

With such a substrate, the invention lies in the selection of a developable interlayer capable of acting as a cobalt diffusion barrier and able, on the one hand, to form chemical bonds with the WC substrate so as to ensure good adhesion and, on the other hand, to promote the nucleation and growth of the diamond and in the two treatments with which said interlayer is associated.

The first of these treatments is a diamond polishing of the surface of this interlayer after deposition on the Co—WC substrate and the second is a thermal annealing between 400 and 700° C. of the substrate/interlayer assembly.

Specifically in the case of a substrate of the Co—WC type, direct deposition of a diamond layer on such a substrate results in very inhomogeneous layers, the cobalt preferentially inducing the formation of graphite. This is why a diamond deposition must be preceded by extraction of the surface cobalt or by masking or by mobilization of the cobalt in a very stable phase.

Cobalt extraction results in a disturbed and non-dense substrate surface, and therefore in a surface that is relatively inappropriate to promoting adhesion to the diamond layer. Mobilization of the cobalt results in heterogeneity of the surface layer of the substrate and therefore modifies the adhesion of the diamond layer.

On the other hand, cobalt masking involves the creation of an effective diffusion barrier, while allowing nucleation and growth of the diamond. The invention proposes for this purpose the polishing of the interlayer.

The second treatment is the annealing of the substrate/interlayer assembly.

More precisely, the main features of the invention are:

1. The selection of an interlayer having mainly three functions, namely:
of being an effective diffusion barrier, hence the choice as interlayer of a material containing strong bonds;
of promoting Co—WC substrate/interlayer adhesion, for which it is necessary for the chemical bonds within the material chosen as interlayer to be compatible with the W—C bonds; and
of allowing nucleation of the diamond on its surface and diamond layer/interlayer adhesion.

Since the diamond is carbon, the composition of the interlayer was chosen in such a way that it promotes bonding to the substrate WC and to the diamond C. Furthermore, since the CVD diamond deposition process involves bombarding the interlayer with carbon-containing species, an interlayer composition capable of developing during the diamond deposition phase was selected.

Two compositions were chosen:
Ti(C,N), consisting in fact of a TiC layer on a TiN layer;
Ti₂N.

After phase 3 and deposition, the composition of these two layers is approximately TiC₁₋ₓNₓ.

2. Choice of an interlayer surface treatment.

The main objective in selecting the interlayer is for it to act as a diffusion barrier with respect to cobalt, the purpose of the second step of the process is to increase the diamond nucleation density at the surface of the interlayer.

Trials in which diamond is deposited on an untreated interlayer, such as Ti(C,N) or Ti₂N (nominal initial compositions), leads to a low nucleation density.

It has been found that a polishing treatment carried out on this interlayer using very fine (0.10 μm) diamond particles dispersed in a felt results, after CVD diamond deposition, in a very great increase in the nucleation density for the same deposition times.

Since the second step has the purpose of activating the nucleation of the diamond on the surface of the interlayer, a third step intended to promote substrate/interlayer adhesion was introduced. Since the phenomenon of adhesion correlates mainly with the creation of chemical bonds, the third phase consisted of thermal annealing.

3. Thermal annealing of the substrate/interlayer assembly.

This assembly is annealed at an optimized temperature of 650° C. for a [Ti(C,N) or Ti₂N] interlayer thickness of around 3 μm and a WC substrate alloyed with 6% Co.

Three important characteristics have then been demonstrated:
titanium and carbon diffusion into WC, therefore forming a (W₁₋ₓTiₓC) “bonding” interface;
safeguarding of the effectiveness of the interlayer surface treatment; and
considerable increase in the diamond nucleation density.

It is therefore apparent that the process involving three successive steps according to the invention results in adherent diamond layers of excellent quality on the surface of a cobalt-alloyed WC substrate.

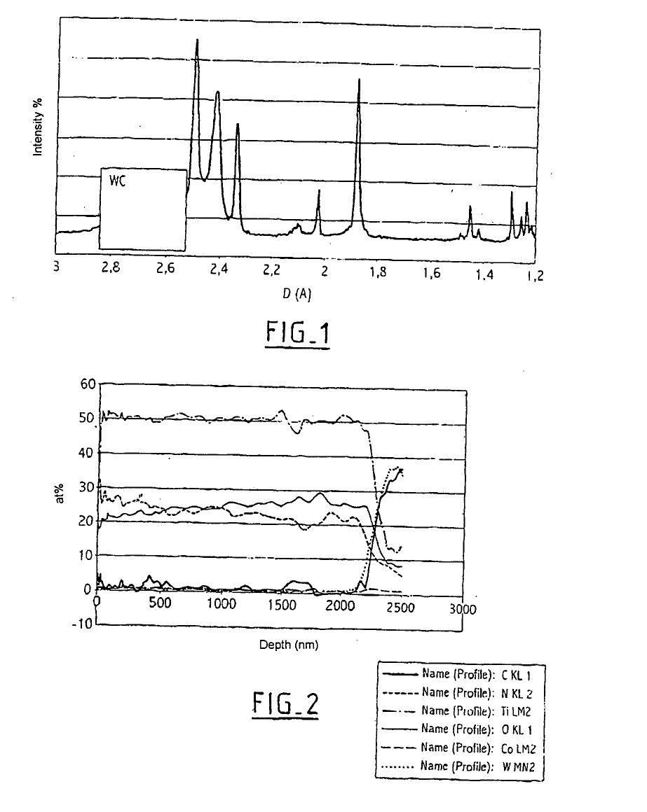

The invention will be more clearly understood from reading the following examples, with reference to FIGS. 1 to 13 in which:

FIG. 1 is an X-ray diffraction pattern of the Ti₂N film deposited on a 5% Co—WC substrate;

FIG. 2 is a concentration profile obtained by Auger spectroscopy of the Ti₂N film deposited on a 5% Co—WC substrate containing approximately 25% oxygen;

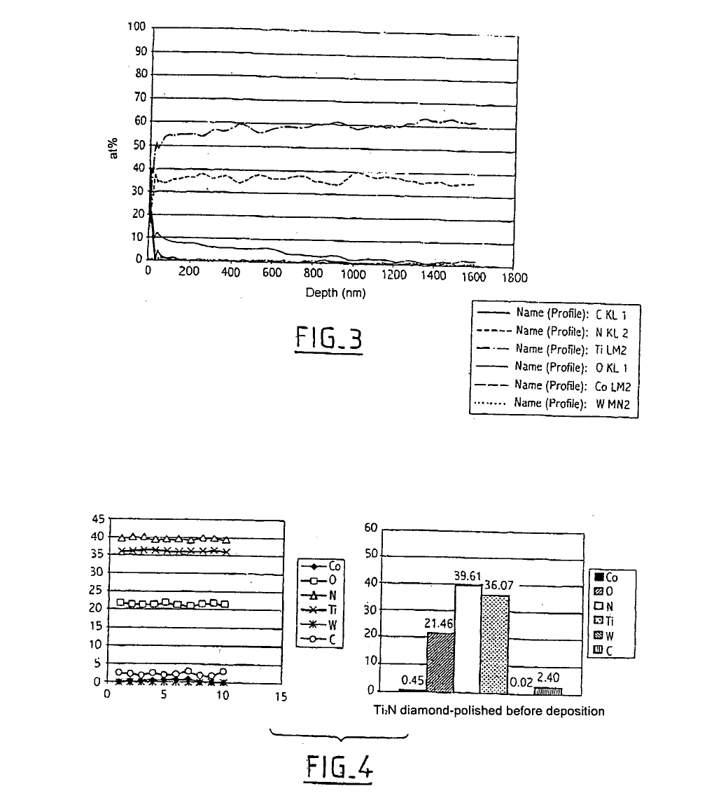

FIG. 3 is a concentration profile obtained by Auger spectroscopy of the Ti₂N film deposited on a 5% Co—WC substrate containing approximately 5% oxygen;

FIG. 4 is a Castaing microprobe (X-ray microprobe) analysis of the Ti₂N film deposited on a Co—WC substrate;

FIG. 5 is an X-ray diffraction pattern of the diamond film deposited on a cobalt (5%)-alloyed WC substrate coated with 0.10 μm-diamond-polished Ti₂N;

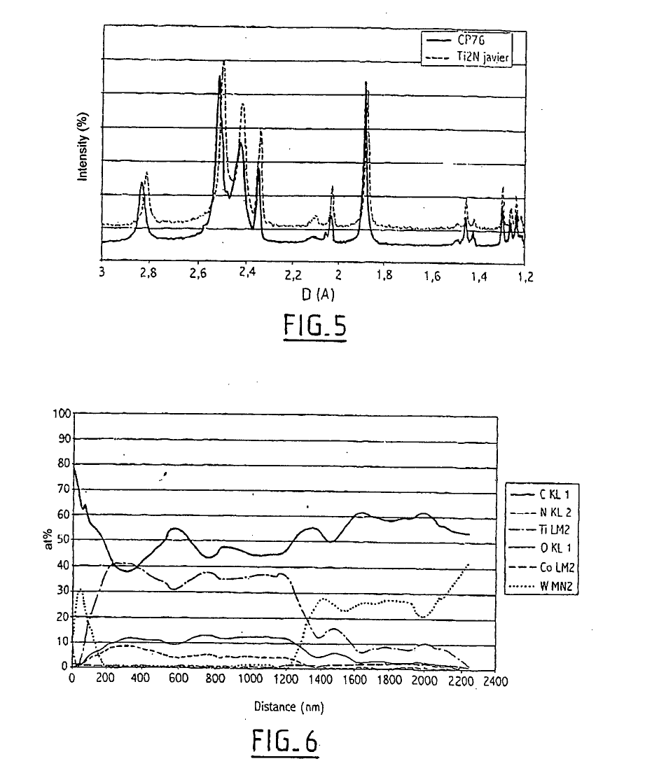

FIG. 6 is a concentration profile obtained by Auger spectroscopy of the Ti₂N film deposited on a 5% Co—WC substrate containing approximately 25% oxygen;

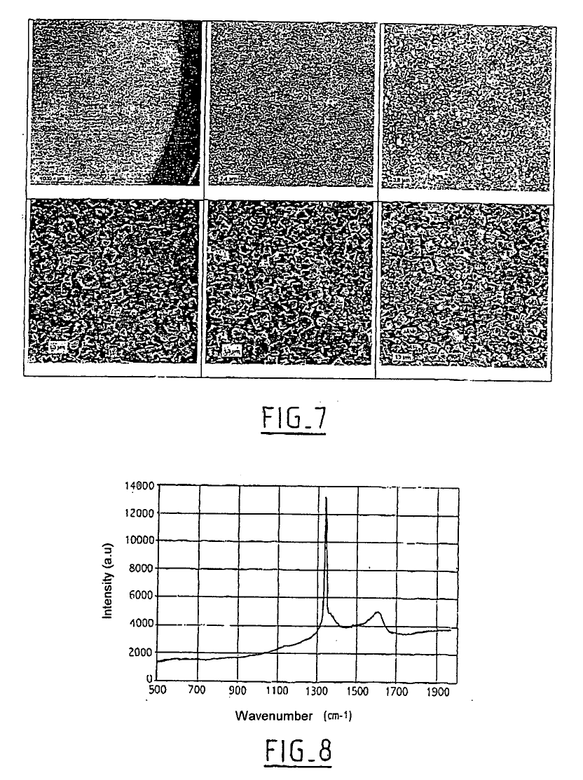

FIG. 7 shows micrographs of the diamond film deposited;

FIG. 8 shows the Raman spectrum of the diamond coating;

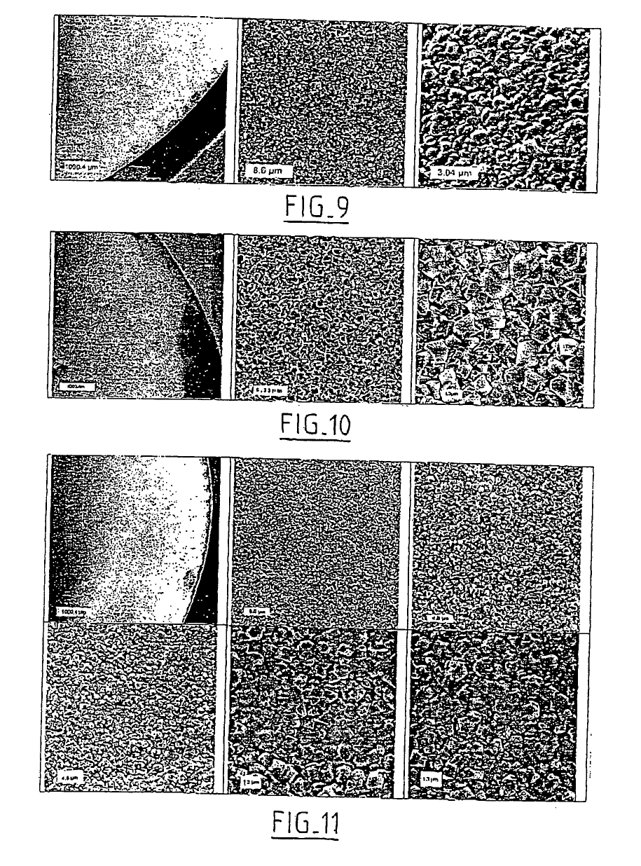

FIG. 9 shows micrographs of the diamond film deposited;

FIG. 10 shows micrographs of the diamond film deposited;

FIG. 11 shows micrographs of the diamond film deposited;

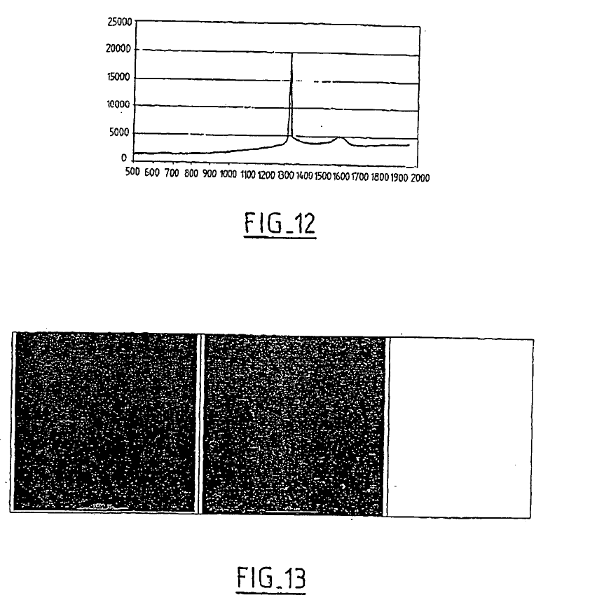

FIG. 12 shows the Raman spectrum of the diamond coating; and

FIG. 13 shows micrographs of a diamond coating on an unpretreated Ti₂N intermediate film.

### EXAMPLE 1

A specimen of cobalt-alloyed tungsten carbide, with a cobalt concentration of 5%, of cylindrical or cubic geometry, was firstly coated with a film of titanium heminitride, i.e. Ti₂N.

The Ti₂N was deposited using the technique of PVD (Physical Vapor Deposition).

A titanium bar, after having been melted by an electron gun, was sputtered in a chamber under reduced pressure, confining a nitrogen plasma. The titanium then reacted with the nitrogen plasma and condensed on the surface of the cobalt-alloyed tungsten carbide substrate by means of a bias.

The PVD Ti₂N deposition took place at a pressure of 10⁻³ mbar of pure nitrogen and a pressure of 100 watts. The growth rate of the film was maintained between 3.5 and 4.5 Å/s for a total thickness of between 1 and 5 μm.

The Ti₂N film thus obtained was characterized by X-ray diffraction, by Auger spectroscopy and by Castaing microprobe (X-ray microprobe).

In a second step, the Ti₂N film deposited on the cobalt-alloyed tungsten carbide substrate was then polished using a diamond suspension (diamond particles #0.1 μm).

In a third step, the cobalt-alloyed tungsten carbide substrate coated with the surface-treated Ti₂N film was then introduced into a hot-filament CVD (Chemical Vapor Deposition) chamber.

The deposition process started with an annealing step at 650° C. for 60 minutes in a stream of pure hydrogen at a pressure of between 20 and 50 mbar and a flow rate of 300 sccm (standard cubic centimeters per minute).

After this annealing for 60 minutes, the carbon-containing species were introduced, in the form of CH₄, into the hydrogen stream (0.7% CH₄).

Using this technique, tungsten filaments (0.1 mm) were heated by the Joule effect by passing a high current (20-35 V, 10-20 A) through them.

The experimental conditions employed were the following:
temperature of the filaments (5×W, Ø 0.1 mm): 2000° C.;
temperature of the substrate: 800-850° C.;
pressure: 30 mbar;
gas (0.7% CH₄; 99.3% H₂) flow rate: 300 sccm; and
deposition time: 6 hours.

The substrates made of cobalt-alloyed tungsten carbide coated with a film of 0.10 μm-polished Ti₂N interlayer and coated with a diamond film were characterized by:
X-ray diffraction (FIG. 5);
Auger spectroscopy (FIG. 6);
scanning electron microscopy (SEM) (FIG. 7);
Raman spectroscopy (FIG. 8); and
X-ray microprobe (Castaing microprobe).

### EXAMPLE 2

### Influence of the Cobalt Concentration

A specimen of cobalt-alloyed tungsten carbide with a cobalt concentration of 16% and a cylindrical or cubic geometry was firstly coated with a film of titanium heminitride, i.e. Ti₂N.

The Ti₂N was deposited under the same conditions as those described in Example 1.

The Ti₂N surface treatment was identical to that described in Example 1.

The annealing of the Ti₂N interlayer/substrate assembly thus treated was carried out under the same conditions as those described in Example 1.

Diamond was deposited under the same conditions as those described in Example 1.

The photographs obtained by scanning electron microscopy of the diamond layer show excellent particle size uniformity and excellent distribution over the substrate.

This example shows that the result obtained is very insensitive to the amount of cobalt contained in the cobalt-alloyed WC substrate. The Ti₂N film therefore also acts as a diffusion barrier.

### EXAMPLE 3

### Influence of the Annealing of the Interlayer/Substrate Assembly.

A specimen of cobalt-alloyed tungsten carbide with a cobalt concentration of 5% and a cylindrical or cubic geometry was firstly coated with a film of titanium heminitride, i.e. Ti₂N.

The Ti₂N was deposited under the same conditions as those described in Example 1.

The Ti₂N surface treatment was identical to that described in Example 1.

No annealing of the interlayer/substrate assembly was carried out.

Diamond was deposited under the same conditions as those described in Example 1.

The absence of annealing in this example demonstrates a much greater difference in the size of the diamond crystallites. The adhesion of the diamond layer is also weaker (FIG. 10).

### EXAMPLE 4

### Influence of the Nature of the Intermediate Film

A specimen of cobalt-alloyed tungsten carbide with a cobalt concentration of 5% and a cylindrical or cubic geometry was firstly coated with a film of titanium carbonitride (Ti(C,N)).

The (Ti(C,N)) surface treatment was identical to that described in Example 1.

The annealing of the (Ti(C,N)) interlayer/substrate assembly thus treated was carried out under the same conditions as those described in Example 1.

Diamond was deposited under the same conditions as those described in Example 1.

The photographs obtained by scanning electron microscopy are given in FIG. 11. The Raman characterization is given in FIG. 12.

In this example, the change in the nature of the intermediate film does not have a great influence on the nucleation density and on the particle size. The main change involves the weaker adhesion of the diamond film to the substrate.

### EXAMPLE 5

### Influence of the Pretreatment of the Interlayer/Substrate Assembly

A specimen of cobalt-alloyed tungsten carbide with a cobalt concentration of 5% and a cylindrical or cubic geometry was firstly coated with a film of titanium heminitride, i.e. Ti₂N.

The Ti₂N was deposited under the same conditions as those described in Example 1.

No surface treatment was carried out on the Ti₂N film. No annealing of the interlayer/substrate assembly was carried out.

Diamond was deposited under the same conditions as those described in Example 1.

In this example, in which no pretreatment of the interlayer took place, no diamond formation was observed (FIG. 13).

Contrary to all the prior art in the Preliminary Search Report, the present patent application defines a novel and inventive process resulting in the application of a developable layer according to a novel concept.

1. A process for manufacturing a diamond-coated composite comprising a substrate consisting of a cobalt-alloyed tungsten carbide WC, the proportion of cobalt by weight ranging from 3 to 20%, in which process the following are carried out in succession: deposition on the substrate of an interlayer of titanium heminitride or titanium carbonitride capable of forming chemical bonds with the substrate and with a diamond coating, surface treatment of the interlayer, annealing of the substrate/interlayer assembly and deposition of the diamond coating by CVD techniques.

2. The method as claimed in claim 1, characterized in that the surface treatment of the interlayer is a polishing treatment.

3. Diamond-coated composites obtained by the process as claimed in either of claims 1 and 2.

4. Articles or parts made of a diamond-coated composite as claimed in claim 3.
